(19) United States
(12) Patent Application Publication
(10) Pub. No.: US 2026/0339053 A1
(43) Pub. Date: Oct. 29, 2026

(54) OPTICAL MODULE

(71) Applicant: INNOLIGHT TECHNOLOGY (SUZHOU) LTD., Jiangsu (CN)

(72) Inventors: Zhenzhong WANG, Suzhou (CN); Jia GU, Suzhou (CN)

(73) Assignee: INNOLIGHT TECHNOLOGY (SUZHOU) LTD., Jiangsu (CN)

(21) Appl. No.: 19/123,381

(22) PCT Filed: Sep. 21, 2023
(86) PCT No.: PCT/CN2023/120337

§ 371 Date: Apr. 22, 2025

(30) Foreign Application Priority Data
Nov. 21, 2022 (CN) 202223082524.9

(51) Int. Cl. G02B 6/42; H05K 1/02; H05K 1/14

(52) U.S. Cl. CPC G02B 6/4281; H05K 1/0243; H05K 1/147; H05K 2201/10098; H05K 2201/10121

(57) ABSTRACT

An optical module, comprising a packaging structure wherein an optical transmitting module and/or an optical receiving module are packaged inside the packaging structure; a hard circuit board assembly, comprising a hard circuit board and an electronic element provided on the hard circuit board, the hard circuit board comprising a first surface layer and a second surface layer arranged opposite to each other, and the electronic element comprising a digital signal processor; and a first flexible circuit board, wherein one end of the first flexible circuit board is electrically connected to a light-emitting module and/or a light-receiving module, and the other end extends between the first surface layer and the second surface layer of the hard circuit board, and is electrically connected to the digital signal processor. The optical module has strong anti-interference capabilities, and the crosstalk between multiple transmission channels on the first flexible circuit board thereof is reduced.

This application claims the priority benefit of China application serial no. 202223082524.9, filed on Nov. 21, 2022 and entitled “OPTICAL MODULE”. The entirety of the above-mentioned patent application is hereby incorporated by reference herein and made a part of this specification.

### Technical Field

The present application relates to the technical field of optical transmission, and in particular relates to an optical module.

### Related Art

The hermetic packaging methods in optical modules are divided into two types: TO and BOX packaging. TO packaging is generally used for single-channel packaging, while for multi-channel packaging, BOX packaging is generally adopted. FIG. 1 is a schematic diagram of connection between a typical BOX packaging and a PCB circuit board, that is, the connection between the BOX packaging and the PCB circuit board is implemented through soldering on both sides, and the upper and lower flexible boards adopt a micro-stripline structure. With the improvement of transmission rates, the bandwidth requirements for high-speed transmission continue to increase. However, in the above connection method, the solder points on the surface of the PCB circuit board occupy a large space and introduce a point of impedance discontinuity. Further, the micro-stripline structure has poor anti-interference capabilities, which leads to serious crosstalk problems between channels transmitting high-speed signals, and the bandwidth of the link may not be improved easily as well.

### UTILITY MODEL SUMMARY

Based on the above, it is necessary to provide an optical module to address the above problems.

An optical module, the optical module including:
a packaging structure, an optical transmitting module and/or an optical receiving module are packaged inside;
a hard circuit board assembly, the hard circuit board assembly including a hard circuit board and an electronic element provided on the hard circuit board, the hard circuit board including a first surface layer and a second surface layer arranged opposite to each other, and the electronic element including a digital signal processor; and
a first flexible circuit board, wherein one end is electrically connected to the optical transmitting module and/or the optical receiving module, and the other end extends between the first surface layer and the second surface layer of the hard circuit board and is electrically connected to the digital signal processor.

In one of the embodiments, a portion of the first flexible circuit board located between the first surface layer and the second surface layer of the hard circuit board forms a four-sided ground-surrounded stripline structure.

In one of the embodiments, the stripline structure includes an upper layer, a middle layer, and a lower layer in sequence. The middle layer of the stripline structure includes a signal transmission line. The upper layer and the lower layer of the stripline structure are both ground layers. Both ends of the signal transmission line are connected to ground transmission lines, and the ground transmission lines are electrically connected to the ground layers of the upper layer and the lower layer through conductive holes.

In one of the embodiments, a portion of the first flexible circuit board exposed outside the hard circuit board forms a micro-stripline structure or a stripline structure. The micro-stripline structure includes a signal transmission line and a ground transmission line provided on both sides of the signal transmission line, and the ground transmission line and the signal transmission line are provided in parallel in a direction in which the first flexible circuit board

In one of the embodiments, the packaging structure includes a hermetic box and an electrical signal connection end exposed outside the hermetic box. The electrical signal connection end is used to transmit a radio frequency or high frequency signal, and the electrical signal connection end is electrically connected to the first flexible circuit board. The optical transmitting module and/or the optical receiving module are arranged inside the hermetic box, and the electrical signal connection end is electrically connected to the optical transmitting module and/or the optical receiving module.

In one of the embodiments, the packaging structure includes a carrier board and an optoelectronic chip fixed onto the carrier board. The optoelectronic chip includes the optical transmitting module and/or the optical receiving module, and one end of the first flexible circuit board is fixed onto the carrier board and is electrically connected to the optoelectronic chip.

In one of the embodiments, the first flexible circuit board and the hard circuit board are combined together by pressing.

In one of the embodiments, the digital processor is provided on the first surface layer. The hard circuit board has a conductive via, and the first flexible circuit board located in an inner layer of the hard circuit board is electrically connected to the digital signal processor on a surface of the hard circuit board through the conductive via.

In one of the embodiments, the electrical signal connection end is used to transmit an electrical signal emitted by the optical receiving module to the digital signal processor through the first flexible circuit board and transmit an electrical signal output by the digital signal processor and transmitted to the electrical signal connection end through the first flexible circuit board to the optical transmitting module.

In one of the embodiments, the electrical signal includes a high-speed digital signal.

In one of the embodiments, the packaging structure further includes a protruding portion extending out of the packaging structure. The protruding portion has upper and lower surfaces disposed opposite to each other. The electrical signal connection end is provided on the upper surface of the protruding portion. A power supply terminal is distributively provided on the lower surface of the protruding portion, and the power supply terminal is used to transmit a power source signal. The power supply terminal is connected to a power source module in the packaging structure. The optical module further includes a second flexible circuit board provided parallel to the first flexible circuit board. The power supply terminal is connected to the hard circuit board through the second flexible circuit board.

In one of the embodiments, the second flexible circuit board and the first flexible circuit board are connected to different circuit layers of the hard circuit board.

In one of the embodiments, the packaging structure further includes a protruding portion extending out of the packaging structure. The protruding portion has upper and lower surfaces disposed opposite to each other. The electrical signal connection end is provided on the upper surface of the protruding portion. A power supply terminal is distributively provided on the lower surface of the protruding portion. The power supply terminal is used to transmit a power source signal. The power supply terminal is connected to a power source module in the packaging structure, and the power supply terminal is connected to the hard circuit board through a connector or the hard circuit board.

In one of the embodiments, the first flexible circuit board is used to transmit a high-speed signal, and the second flexible circuit board is used to transmit a low-speed signal.

In one of the embodiments, a length of the first flexible circuit board exposed outside the hard circuit board is between 3 millimeters and 8 millimeters.

In the above optical module, the electrical signal connection end on the packaging structure is connected to the hard circuit board through the first flexible circuit board. The first flexible circuit board is not directly soldered onto the hard circuit board, but extends to the inner layer of the hard circuit board through the flexible-hard combined board process method and then is further electrically connected to the digital signal processor. That is, the flexible-hard board combined connection method is adopted to implement the electrical connection between the packaging structure and the hard circuit board. Since most of the first flexible circuit board is located in the inner layer of the hard circuit board, a four-sided ground-surrounded stripline form is adopted. Compared to the conventional micro-stripline structure, stronger anti-interference capabilities are provided, and the crosstalk between multiple transmission channels on the first flexible circuit board is reduced. Further, since the first flexible circuit board is not directly soldered to the surface of the hard circuit board, the space occupied by solder joints on the surface of the hard circuit board is decreased. By reducing one solder point, the bandwidth loss caused by discontinuity points is lowered, the crosstalk between multiple transmission channels is further reduced, while the link bandwidth and ornament space is increased.

### DESCRIPTION OF THE DRAWINGS

FIG. 1 is a structural schematic diagram of an optical module of the related art.

FIG. 2 is a structural schematic diagram of an optical module provided by the embodiments of the present application.

FIG. 3 is a partial enlarged schematic view of a position M in FIG. 2.

FIG. 4 is a structural schematic diagram of another optical module provided by the embodiments of the present application.

### DESCRIPTION OF REFERENCE NUMERALS

100: packaging structure, 110: electrical signal connection end, 120: optical interface, 130: power supply terminal, 140: hermetic box, 200: hard circuit board assembly, 210: digital signal processor, 220: hard circuit board 1, 222: first surface layer, 224: second surface layer, 230: conductive contact, 240: conductive via, 300: first flexible circuit board, 310: micro-stripline structure, 320: stripline structure, 400: second flexible circuit board.

### SPECIFIC EMBODIMENTS

To facilitate understanding of the disclosure, the disclosure will be described more comprehensively below with reference to the relevant accompanying drawings. The embodiments of the present application are illustrated in the accompanying drawings. However, the present application can be implemented in many different forms and is not limited to the embodiments described herein. On the contrary, the purpose of providing these embodiments is to make the disclosed content of the present application more thorough and comprehensive.

In the disclosure, unless clearly specified and defined otherwise, the terms “installed”, “connected”, “connecting”, “fixed” and other terms should be understood in a broad sense, for instance, it can be a fixed connection, a detachable connection, or an integral connection, it can be a mechanical connection or an electrical connection, it can be a direct connection or an indirect connection through an intermediate medium, and it can be an internal communication between two components or an interaction relationship between two components, unless clearly defined otherwise. For a person having ordinary skill in the art, the specific meaning of the above-mentioned terms in the disclosure can be understood according to specific circumstances.

The terms “first” and “second” are only used for descriptive purposes and cannot be understood as indicating or implying relative importance or implicitly indicating the number of indicated technical features. Thus, the features defined with “first” and “second” may explicitly or implicitly include at least one of these features. In the description of the disclosure, “plurality” means at least two, such as two, three, etc., unless otherwise expressly and specifically defined.

Unless otherwise defined, all technical and scientific terms used in the specification have the same meaning as commonly understood by a person having ordinary skill in the art. The terms used herein in the specification of the disclosure are for the purpose of describing specific embodiments only, and are not intended to limit the disclosure. As used herein, the term “and/or” includes any and all combinations of one or more of the associated listed items.

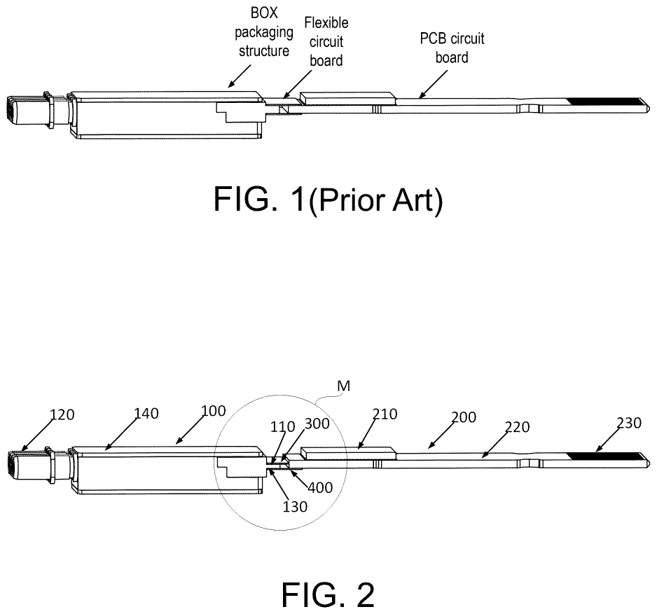

As mentioned in the related art section, for multi-channel signal transmission in an optical module, the BOX packaging structure is generally adopted. Specifically, referring to FIG. 1, the BOX packaging structure is externally connected to a flexible circuit board, the flexible circuit board is soldered with the PCB circuit board, so the electrical connection between the BOX packaging and the PCB circuit board is implemented. The micro-stripline structure is usually adopted on the flexible circuit board. However, the flexible circuit board and the PCB circuit board are connected by soldering, that is, solder points are formed on the PCB circuit board. The solder points need to be assembled and fitted, so additional tolerances are introduced, and all of which lead to the deterioration of bandwidth and crosstalk. Further, the presence of the solder points and micro-stripline structure may lead to crosstalk between high-speed signal transmission channels on the flexible circuit board, and the bandwidth of the link is also small, so the performance of the optical module is thus lowered.

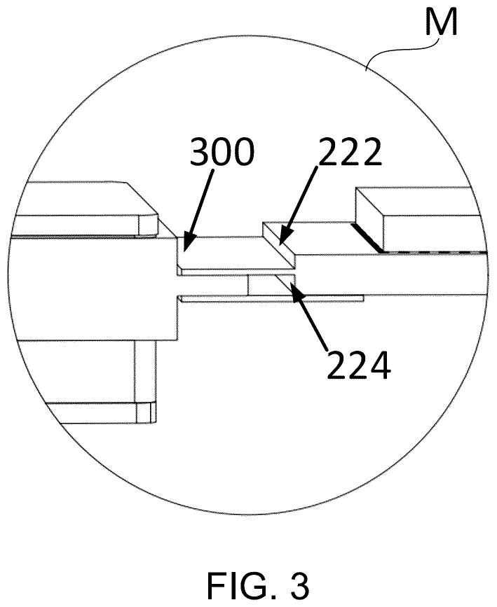

Accordingly, the present application provides an optical module. Referring to FIG. 2 and FIG. 3, the optical module provided in this embodiment includes a casing, a packaging structure 100, a hard circuit board assembly 200, and a first flexible circuit board 300. The packaging structure 100, the hard circuit board assembly 200, and the first flexible circuit board 300 are provided inside the casing. Wherein:

The packaging structure 100 internally packages an optical transmitting module and/or an optical receiving module (not shown in the figure), and the packaging structure 100 includes the optical transmitting module and/or the optical receiving module. The hard circuit board assembly 200 includes a hard circuit board 220 and an electronic element provided on the hard circuit board 220, for example, a digital signal processor 210 is provided on the hard circuit board 220. The hard circuit board includes a first surface layer 222 and a second surface layer 224 that are arranged opposite to each other. The first surface layer 222 and the second surface layer 224 of the hard circuit board are an outermost upper and lower circuit layers of the hard circuit board in this embodiment. In other embodiments, the first surface layer 222 and the second surface layer 224 may also be any two circuit layers between the outermost circuit layers, or one of them may be the outermost circuit layer and the other one is a circuit layer between the outermost circuit layers. That is, the hard circuit board may have more than three layers, it may be a circuit board with four, five, seven or more layers. The first surface layer and the second surface layer are two of these layers, and the first flexible circuit board is one-layer or multi-layer circuit board formed between the first surface layer and the second surface layer. One end of the first flexible circuit board 300 is electrically connected to the optical transmitting module and/or the optical receiving module, and the other end extends between the first surface layer 222 and the second surface layer 224 of the hard circuit board 220 and is electrically connected to the digital signal processor 210.

In the above optical module, the hard circuit board 220 may also be provided with other electronic elements, such as an IC (integrated circuit chip), and may also include a substrate for fixing electronic elements, etc. One end of the hard circuit board 220 away from the packaging structure 100 is provided with a conductive contact 230, and the hard circuit board 220 may be pluggably connected to an external device through the conductive contact 230. The packaging structure 100 may adopt a hermetically sealed Box package or may adopt an open carrier board structure. The packaging structure 100 is connected to the hard circuit board 220 through the first flexible circuit board 300. The first flexible circuit board 300 is not directly soldered on the hard circuit board 220, but extends between the first surface layer 222 and the second surface layer 224 of the hard circuit board 220, and then is electrically connected to the digital signal processor 210. That is, the electrical connection between the packaging structure 100 and the hard circuit board 220 is implemented by combining the flexible and hard boards. Since most of the first flexible circuit board 300 is located in an inner layer of the hard circuit board 220, a four-sided ground-surrounded stripline form is adopted. Compared to the conventional micro-stripline structure, stronger anti-interference capabilities are provided, the crosstalk between multiple transmission channels on the first flexible circuit board 300 is reduced, and since the first flexible circuit board 300 is not directly soldered on a surface of the hard circuit board 220, the discontinuous points produced by soldering the flexible circuit board 300 and the hard circuit board 220 are decreased. Further, since the space occupied by solder points is reduced, the routing length may also be shortened, the crosstalk between multiple transmission channels is lowered, and the link bandwidth and ornament space are increased.

To be specific, the optical transmitting module packaged in the packaging structure 100 may include an optical emitting chip, such as a laser chip, etc. Any device that can implement electrical-to-optical conversion is applicable to the present application.

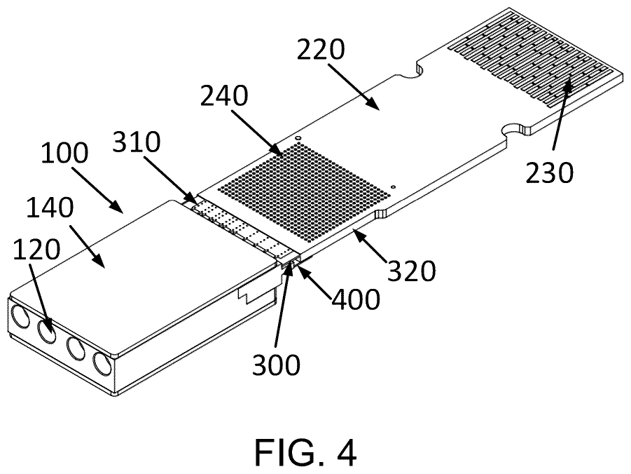

In one of the embodiments, referring to FIG. 4, the portion of the first flexible circuit board 300 located between the first surface layer 222 and the second surface layer 224 of the hard circuit board 220 forms a four-sided ground-surrounded stripline structure 320, and a portion of the first flexible circuit board 300 exposed outside the hard circuit board 220 forms a micro-stripline structure 310. That is, a region between an electrical signal connection end 110 and an edge of the hard circuit board 200 is the micro-stripline structure 310.

In this embodiment, the stripline structure 320 includes an upper layer, a middle layer, and a lower layer in sequence. The middle layer of the stripline structure 320 includes a signal transmission line. Herein, the signal transmission line of the stripline structure 320 may be provided on the first flexible circuit board 300, and a dielectric material may be filled among the upper layer, the middle layer, and the lower layer of the stripline structure 320. The upper layer and the lower layer of the stripline structure 320 are both ground layers, and Ground transmission lines are connected to both ends of the signal transmission lines. The ground transmission lines are electrically connected to the ground layers of the upper layer and the lower layer through conductive holes. Herein, the ground layers of the upper layer and the lower layer of the stripline structure 320 may be independently arranged ground layers, or may be arranged on the sides facing the first surface layer 222 and the second surface layer 224 of the hard circuit board 220. The micro-stripline structure 310 includes a signal layer and a lower layer in sequence. The micro-stripline structure 310 includes a signal transmission line and a ground transmission line provided on both sides of the signal transmission line, and the ground transmission line and the signal transmission line are provided in parallel in a direction in which the first flexible circuit board extends out of the hard circuit board.

In this embodiment, the region between the electrical signal connection end 110 and the edge of the hard circuit board 200 may also be arranged as a stripline structure. That is, the region between the electrical signal connection end 110 and the edge of the hard circuit board 200 may be a micro-stripline structure or a stripline structure.

In one of the embodiments, referring to FIG. 2 again, the packaging structure 100 adopts hermetic Box packaging. The packaging structure 100 includes a hermetic box 140 and the electrical signal connection end 110 exposed outside the hermetic box 140, and the electrical signal connection end 110 is electrically connected to the first flexible circuit board 300. The optical transmitting module and/or the optical receiving module are arranged inside the hermetic box 140. Wherein, the electrical signal connection end 110 is electrically connected to the optical transmitting module and/or the optical receiving module.

Wherein, the electrical signal connection end 110 is used to transmit an electrical signal output by the digital signal processor 210 and transmitted to the electrical signal connection end 110 through the first flexible circuit board 300 to the optical transmitting module.

The optical transmitting module may be connected to the electrical signal connection end 110 through a connection line inside the packaging structure 100, and the electrical signal connection end 110 is electrically connected to the digital signal processor 210 on the hard circuit board 220 through the first flexible circuit board 300. Accordingly, the electrical signal generated by the digital signal processor 210 may be transmitted to the electrical signal connection end 110 through the first flexible circuit board 300 and then transmitted to the optical transmitting module inside the packaging structure 100 through the electrical signal connection end 110. The optical transmitting module may convert the electrical signal into an optical signal and output the optical signal externally.

The optical receiving module packaged inside the packaging structure 100 may include an optical signal detection device such as a photodiode that is capable of converting light into electricity. The packaging structure 100, through the electrical signal connection end 110, may transmit the electrical signal emitted by the optical receiving module to the digital signal processor 210 through the first flexible circuit board.

The optical receiving module may be connected to the electrical signal connection end 110 through the connection line inside the packaging structure 100. The optical receiving module and the optical transmitting module use parallel connection lines and do not interfere with each other. The electrical signal connection end 110 is electrically connected to the digital signal processor 210 on the hard circuit board 220 through the first flexible circuit board 300, so that the electrical connection between the digital signal processor 210 and the optical receiving module is implemented. After receiving the optical signal, the optical receiving module converts the optical signal into an electrical signal, transmits the electrical signal to the electrical signal connection end 110, and then transmits the electrical signal to the digital signal processor 210 on the hard circuit board 220 through the electrical signal connection end 110.

Signal transmission channels among the optical receiving module, the electrical signal connection end 110, and the digital signal processor 210 are arranged in parallel with signal transmission channels among the optical transmitting module, the electrical signal connection end 110, and the digital signal processor 210 without interfering one another.

In this embodiment, the electrical signal emitted by the digital signal processor 210 as well as the electrical signal converted by the optical receiving module may include high-speed digital signals.

In this embodiment, the packaging structure 100 further includes an optical interface 120. The optical interface is connected to the optical receiving module, used to receive an optical signal from the outside, and send the received optical signal to the optical receiving module. The optical receiving module converts the optical signal into an electrical signal and output the electrical signal to the electrical signal connection end 110.

In this embodiment, the electrical signal connection end 110 is exposed outside a main body of the packaging structure 100, which may facilitate the connection between the electrical signal connection end 110 and the first flexible circuit board 300. Wherein, the first flexible circuit board 300 and the electrical signal connection end 110 may be electrically connected through methods such as soldering or ACF pressing. In addition, the first flexible circuit board 300 extends into the inner layer of the hard circuit board 220. That is, different from the conventional method of soldering the first flexible circuit board 300 on the surface of the hard circuit board 220, the first flexible circuit board 300 is provided inside the hard circuit board 220 in this embodiment, so as to implement the connection between the first flexible circuit board 300 and the hard circuit board 220 through a combination of flexible and hard boards.

Generally, a portion of the first flexible circuit board 300 that extends into the inner layer of the hard circuit board 220 penetrates through the hard circuit board 220 in an extending direction. This is because if the first flexible circuit board 300 does not penetrate through the inner layer of the hard circuit board 220, a thickness of the hard circuit board 220 is inconsistent, with the thickness at the position where the first flexible circuit board 300 is present being greater than the thickness at the position where the first flexible circuit board 300 is not present. In a preparation process, it may be necessary to consider increasing the thickness of the thinner portions, so the preparation is undoubtedly complicated. In this embodiment, the first flexible circuit board 300 penetrates through the hard circuit board 220, so the thickness of each location in the hard circuit board 220 remains consistent, and the preparation process is thus simplified.

In this embodiment, the first flexible circuit board 300 and the hard circuit board 220 are connected through a pressing method. The first flexible circuit board 300 may include a base board and copper foil layers disposed above and below the base board. In the actual preparation process, the abovementioned structural layers of the first flexible circuit board 300 may be pressed together with the circuit layers in the hard circuit board 220 to form a flexible-hard combined board.

The design of the abovementioned flexible-hard combined board does not require soldering. Compared to assembling the first flexible circuit board 300 with the hard circuit board 220 through soldering, the number of solder points is lowered, that is, the discontinuous points on the signal transmission channels are reduced. Further, for the conventional soldering method, due to the circuit manufacturing tolerances of the board factory, assembly misalignment tolerances of soldering, and solder quantity control issues, the high-frequency link would deviate from the actual design model, so high-frequency performance is damaged. However, in the design of the flexible-hard combined board in this embodiment, the problem of high-frequency signal damage caused by the soldering method is effectively avoided.

In one of the embodiments, the packaging structure 100 adopts a non-hermetic carrier board structure. The packaging structure 100 includes a carrier board and an optoelectronic chip fixed onto the carrier board, and the optoelectronic chip may include an optical transmitting module and/or an optical receiving module. Wherein, one end of the first flexible circuit board 300 is fixed onto the carrier board and is electrically connected to the optoelectronic chip, for example, through gold wire electrical connection.

In one of the embodiments, a length of the first flexible circuit board 300 exposed outside the hard circuit board 220 is between 3 millimeters and 8 millimeters.

In the conventional technique, the first flexible circuit board 300 is soldered to the surface of the hard circuit board 220, and the first flexible circuit board 300 is mostly exposed, with the exposed length being at least 10 millimeters. The more the first flexible circuit board is exposed, the more micro-stripline structures there are, and the easier it is for crosstalk to occur between the signal transmission channels. In the present application, most regions of the first flexible circuit board 300 are located in the inner layer of the hard circuit board 220, and the exposed region is only the region between the electrical signal connection end 110 and the edge of the hard circuit board 220, with a length of only between 3 millimeters and 8 millimeters, which is far less than the conventional 10 millimeters. That is, in the signal transmission channels, the stripline structure is adopted most of the time, with the micro-stripline structure occupying only 3 millimeters to 8 millimeters, so that the crosstalk problem brought by the conventional micro-stripline structure is effectively reduced.

In one of the embodiments, the hard circuit board 220 has a conductive vias 240, and the first flexible circuit board 300 located between the first surface layer 222 and the second surface layer 224 of the hard circuit board 220 is electrically connected to the digital signal processor 210 on the surface of the hard circuit board 220 through the conductive via 240.

The first flexible circuit board 300 extending into the hard circuit board 220 needs to communicate with the digital signal processor 210 on the surface layer of the hard circuit board 220, so as to implement the electrical connection between the optical receiving module or the optical transmitting module and the digital signal processor 210. In this embodiment, the conductive via is provided on the hard circuit board 220 at the position corresponding to the digital signal processor 210, so that the conductive via can communicate with the digital signal processor 210 and the first flexible circuit board 300. The electrical communication between the digital signal processor 210 and the first flexible circuit board 300 is implemented by arranging a conductive material such as metal inside the conductive via.

In practical applications, a plurality of digital signal processors 210 may be provided on the hard circuit board 220, and it is sufficient to electrically connect the digital signal processors 210 associated with the optical receiving module and the optical transmitting module to the first flexible circuit board 300.

In one of the embodiments, the digital signal processor 210 includes a DSP chip.

With the increase in speed, the bandwidth required for high-speed also continues to grow, developing from single-channel 25G to 53G, 100G, etc. When speeds of 53G and beyond are used, the digital signal processor 210 needs to use a DSP chip. The arrangement of the DSP chip occupies a relatively large space, which places higher demands on the space of the hard circuit board 220. If conventional methods are adopted, the hard circuit board 220 needs to be provided with a solder pad required for connection with the first flexible circuit board 300. The solder pad and the avoidance space reserved for the soldering operation occupy a large space on the hard circuit board 220, which may result in insufficient space on the hard circuit board 220 for arranging the DSP chip. It may be necessary to lengthen the hard circuit board 220 or use a mother-daughter board structure to expand the space, but the mother-daughter board structure may bring about the problem of affecting heat dissipation.

Facing the above difficulties, in the solution of this embodiment, through the method of adopting the flexible-hard combined board, the number of solder pads on the hard circuit board 220 is reduced. Therefore, space is saved for the hard circuit board 220, the hard circuit board 220 has sufficient space for component layout, and the space utilization of the hard circuit board 220 is effectively improved. Based on the above, the DSP chip can be provided on the hard circuit board 220, the transmission and processing of high-speed signals are ensured, and the entire high-speed link design control is also relatively easy. Further, the design of the flexible-hard combined board shortens the channel distance from the DSP chip to the optical receiving (or emitting) module, discontinuous points are decreased, and the bandwidth of the link is increased.

In this embodiment, the packaging structure 100 further includes an exposed power supply terminal 130. The power supply terminal 130 is connected to the surface of the hard circuit board 220 through the second flexible circuit board 400, and the power supply terminal 130 is arranged opposite to the electrical signal connection end 110. The power supply terminal 130 is electrically connected to a power source module in the packaging structure 100. The power source module referred to herein is the module in the packaging structure 100 that requires power supply, such as the optical transmitting module. That is, the power source module in the packaging structure 100 may provide power through the power supply terminal 130. Since the power supply terminal 130 is connected to the surface of the hard circuit board 220 through the second flexible circuit board 400, the hard circuit board 220 may power the relevant devices in the packaging structure 100 through the second flexible circuit board 400. In other embodiments, the optical module may also include the first flexible circuit board only, and the hard circuit board may simultaneously achieve power supply and signal transmission to the packaging structure through the first flexible circuit board.

Wherein, the second flexible circuit board 400 may be connected to the hard circuit board 220 through a connector or by soldering. This improves the operability of the process and assembly tolerance.

In one of the embodiments, the packaging structure 100 further includes the exposed power supply terminal 130. The power supply terminal 130 is arranged opposite to the electrical signal connection end 110, the power supply terminal 130 is connected to the power source module in the packaging structure 100, and the power supply terminal 130 is connected to the second surface of the hard circuit board 220 through a connector (e.g., a pin) or a circuit board.

In one of the embodiments, the first flexible circuit board 300 is used to transmit a high-speed signal, and the second flexible circuit board 400 is used to transmit a low-speed signal.

As mentioned in the foregoing paragraphs, the first flexible circuit board 300 may provide a high-speed signal channel between the optical receiving (or emitting) module and the digital signal processor 210, while the second flexible circuit board 400 is for providing a low-speed signal such as power supply to the hard circuit board 220. That is, between the packaging structure 100 and the hard circuit board 220, both high-speed signal transmission and low-speed signal transmission are present. In the present application, for high-speed signals, the first flexible circuit board 300 is provided and pressed with the hard circuit board 220 to form the flexible-hard board structure, so that the crosstalk problem that easily occurs during high-speed signal multi-channel transmission is specifically reduced, while link bandwidth is increased. For low-speed signals, the second flexible circuit board 400 is provided, and the packaging structure 100 is connected to the hard circuit board 220 through the second flexible circuit board 400 for low-speed signal transmission. Transmitting low-speed signals and high-speed signals through different flexible circuit boards makes it easier to distinguish different signals for transmission, so as to specifically solve the problems that are present in the transmission process of different signals.

The technical features of the above-described embodiments may be combined arbitrarily. In order to simplify the description, not all possible combinations of the technical features in the above embodiments are described. However, as long as there is no contradiction in the combinations of these technical features, these combinations should be considered to be within the scope of the description in this specification.

The abovementioned embodiments only represent several embodiments of the present application, and the descriptions thereof are specific and detailed, but should not be construed as a limitation on the scope of the patent. It should be pointed out that for a person having ordinary skill in the art, without departing from the concept of the present application, several modifications and improvements can be made, which all belong to the protection scope of the present application. Therefore, the protection scope of the present application should be subject to the appended claims.

1. An optical module, comprises:
a packaging structure, wherein an optical transmitting module and/or an optical receiving module are packaged inside;
a hard circuit board assembly, the hard circuit board assembly comprising a hard circuit board and an electronic element provided on the hard circuit board, the hard circuit board comprising a first surface layer and a second surface layer arranged opposite to each other, and the electronic element comprising a digital signal processor; and
a first flexible circuit board, wherein one end is electrically connected to the optical transmitting module and/or the optical receiving module, and the other end extends between the first surface layer and the second surface layer of the hard circuit board and is electrically connected to the digital signal processor.

2. The optical module according to claim 1, wherein a portion of the first flexible circuit board located between the first surface layer and the second surface layer of the hard circuit board forms a four-sided ground-surrounded stripline structure.

3. The optical module according to claim 2, wherein the stripline structure comprises an upper layer, a middle layer, and a lower layer in sequence, the middle layer of the stripline structure comprises a signal transmission line, the upper layer and the lower layer of the stripline structure are both ground layers, both ends of the signal transmission line are connected to ground transmission lines, and the ground transmission lines are electrically connected to the ground layers of the upper layer and the lower layer through conductive holes.

4. The optical module according to claim 3,
wherein a portion of the first flexible circuit board exposed outside the hard circuit board forms a micro-stripline structure or a stripline structure, the micro-stripline structure comprises a signal transmission line and a ground transmission line provided on both sides of the signal transmission line, and the ground transmission line and the signal transmission line are provided in parallel in a direction in which the first flexible circuit board extends out of the hard circuit board.

5. The optical module according to claim 1, wherein the packaging structure comprises a hermetic box and an electrical signal connection end exposed outside the hermetic box, the electrical signal connection end is used to transmit a radio frequency or high frequency signal, the electrical signal connection end is electrically connected to the first flexible circuit board, the optical transmitting module and/or the optical receiving module are arranged inside the hermetic box, and the electrical signal connection end is electrically connected to the optical transmitting module and/or the optical receiving module.

6. The optical module according to claim 5, wherein the packaging structure comprises a carrier board and an optoelectronic chip fixed onto the carrier board, the optoelectronic chip comprises the optical transmitting module and/or the optical receiving module, and one end of the first flexible circuit board is fixed onto the carrier board and is electrically connected to the optoelectronic chip.

7. The optical module according to claim 5, wherein the first flexible circuit board and the hard circuit board are combined together by pressing.

8. The optical module according to claim 5, wherein the digital signal processor is provided on the first surface layer, the hard circuit board has a conductive via, and the first flexible circuit board located in an inner layer of the hard circuit board is electrically connected to the digital signal processor on a surface of the hard circuit board through the conductive via.

9. The optical module according to claim 5, wherein the electrical signal connection end is used to transmit an electrical signal emitted by the optical receiving module to the digital signal processor through the first flexible circuit board and transmit an electrical signal output by the digital signal processor and transmitted to the electrical signal connection end through the first flexible circuit board to the optical transmitting module.

10. The optical module according to claim 9, wherein the electrical signal comprises a high-speed digital signal.

11. The optical module according to claim 5, wherein the packaging structure further comprises a protruding portion extending out of the packaging structure, the protruding portion has upper and lower surfaces disposed opposite to each other, the electrical signal connection end is provided on the upper surface of the protruding portion, a power supply terminal is distributively provided on the lower surface of the protruding portion, the power supply terminal is used to transmit a power source signal, the power supply terminal is connected to a power source module in the packaging structure, the optical module further comprises a second flexible circuit board provided parallel to the first flexible circuit board, and the power supply terminal is connected to the hard circuit board through the second flexible circuit board.

12. The optical module according to claim 11, wherein the second flexible circuit board and the first flexible circuit board are connected to different circuit layers of the hard circuit board.

13. The optical module according to claim 5, wherein the packaging structure further comprises a protruding portion extending out of the packaging structure, the protruding portion has upper and lower surfaces disposed opposite to each other, the electrical signal connection end is provided on the upper surface of the protruding portion, a power supply terminal is distributively provided on the lower surface of the protruding portion, the power supply terminal is used to transmit a power source signal, the power supply terminal is connected to a power source module in the packaging structure, and the power supply terminal is connected to the hard circuit board through a connector or the hard circuit board.

14. The optical module according to claim 11, wherein the first flexible circuit board is used to transmit a high-speed signal, and the second flexible circuit board is used to transmit a low-speed signal.

15. The optical module according to claim 11, wherein a length of the first flexible circuit board exposed outside the hard circuit board is between 3 millimeters and 8 millimeters.
